(19) United States
(12) Patent Application Publication
(10) Pub. No.: US 2026/0223496 A1
(43) Pub. Date: Jul. 30, 2026

(54) OPTOELECTRONIC COMPONENT AND METHOD FOR PRODUCING AN OPTOELECTRONIC COMPONENT

(71) Applicant: ams-OSRM International GmbH, Regensburg (DE)

(72) Inventors: Andreas Reith, Steinach (DE); Gunnar Petersen, Regensburg (DE); Daniel Richter, Bad Abbach (DE); Roland Hüttinger, Kaufering (DE)

(21) Appl. No.: 19/151,936

(22) PCT Filed: Feb. 8, 2024
(86) PCT No.: PCT/EP2024/053123

§ 371 Date: Jul. 29, 2025

(30) Foreign Application Priority Data
Feb. 23, 2023 (DE) 10 2023 104 440.0

(51) Int. Cl. H10H 20/851; H10H 20/01; H10H 20/855; H10H 29/24

(52) U.S. Cl. CPC H10H 20/8512; H10H 20/021; H10H 20/0361; H10H 20/0363; H10H 20/855; H10H 29/24

(57) ABSTRACT

In an embodiment an optoelectronic component includes at least one optoelectronic semiconductor chip, at least one optical element and an intermediate layer between the at least one optoelectronic semiconductor chip and the at least one optical element, wherein the intermediate layer is configured to attach the at least one optoelectronic semiconductor chip to the at least one optical element, wherein the at least one optical element comprises a material that is transparent to radiation of a second wavelength range, wherein the intermediate layer comprises a material that is absorbent to the radiation of the second wavelength range, and wherein the intermediate layer is free from an organic material.

### CROSS-REFERENCE TO RELATED APPLICATIONS

This patent application is a national phase filing under section 371 of PCT/EP2024/053123, filed Feb. 8, 2024, which claims the priority of German patent application no. 102023104440.0, filed Feb. 23, 2023, each of which is incorporated herein by reference in its entirety.

### TECHNICAL FIELD

An optoelectronic component is disclosed. In addition, a method of manufacturing an optoelectronic component is disclosed.

### SUMMARY

Embodiments provide an optoelectronic component having high light extraction and a long operational life. Further embodiments provide a method for manufacturing such a component.

According to at least one embodiment of the optoelectronic semiconductor component, the optoelectronic semiconductor component comprises at least one optoelectronic semiconductor chip which is configured to emit radiation in a first wavelength range.

The at least one optoelectronic semiconductor chip comprises, for example, a semiconductor layer sequence with an active zone. The active zone is used to generate or absorb electromagnetic radiation. The active zone is formed, for example, with a III-V compound semiconductor material.

In principle, it is possible that electromagnetic radiation in the blue or green or red spectral range or in the UV range or in the IR range is generated in the active zone during intended operation. Preferably, radiation in the UV range is generated in the intended operation of the active zone, in particular in the so-called UVC range of the electromagnetic spectrum. In particular, the radiation generated in the active zone during operation is radiation of the first wavelength range.

The at least one optoelectronic semiconductor chip further comprises, for example, a chip substrate. The semiconductor layer sequence may be arranged on a main side of the chip substrate. The chip substrate is, for example, a growth substrate of the semiconductor layer sequence. The chip substrate preferably comprises sapphire or is formed from sapphire. Preferably, the at least one optoelectronic semiconductor chip is a volume emitter, in particular a sapphire chip.

Contact points for contacting and current supplying of the semiconductor layer sequence are arranged on a side of the semiconductor layer sequence facing away from the chip substrate. The optoelectronic semiconductor chip is preferably a flip chip.

Preferably, the optoelectronic semiconductor chip is in particular a light-emitting diode, or LED for short. Alternatively, it is possible that the optoelectronic semiconductor chip is a laser diode, such as an edge emitter or a surface-emitting semiconductor laser diode, also known as a VCSEL for short.

According to at least one embodiment, the optoelectronic component comprises at least one optical element. The at least one optical element is, for example, configured for beam shaping of radiation of the first wavelength range. The at least one optical element is, for example, a lens, a prism or a meta-lens structure. During intended operation, radiation emitted by the at least one semiconductor chip can be directed by the optical element, for example in a main emission direction. The main emission direction is preferably perpendicular to a main extension direction of the semiconductor layer sequence or the active zone and is a direction in which the radiation of the first wavelength range, which is emitted by the optoelectronic component during operation, has its intensity maximum.

According to at least one embodiment, the optoelectronic component comprises an intermediate layer arranged between the at least one optoelectronic semiconductor chip and the at least one optical element. The intermediate layer serves, for example, as an adhesion promoter to attach the at least one optical element to the at least one semiconductor chip. Preferably, the intermediate layer is in direct contact with the at least one semiconductor chip and in direct contact with the at least one optical element. The intermediate layer has a thickness of, for example, 1 μm to 5 μm inclusive. A roughness of a surface of the at least one optoelectronic semiconductor chip and/or of the at least one optical element on which the intermediate layer is arranged can advantageously be leveled out by means of the intermediate layer.

For example, the intermediate layer is arranged on a main emission surface of the at least one optoelectronic semiconductor chip. A large proportion, for example at least 50% or at least 75%, of the radiation generated in the active zone is emitted via the main emission surface during intended operation. If the at least one optoelectronic semiconductor chip is a sapphire chip, for example, the main emission surface is in particular a surface of the chip substrate that faces away from the semiconductor layer sequence. If, on the other hand, the optoelectronic semiconductor chip is a laser diode, for example, the main emission surface is preferably a facet of the laser diode.

According to at least one embodiment of the optoelectronic component, the at least one optical element is formed with a material that is transparent to radiation of a second wavelength range. For example, the material of the optical element comprises a glass. Alternatively or additionally, it is possible that the optical element is formed with sapphire and/or quartz. If a material or an element is described here and in the following as “transparent” for a certain radiation, it has in particular a transmittance of at least 80% or at least 90% or at least 95% with respect to this radiation.

According to at least one embodiment of the optoelectronic component, the intermediate layer comprises a material which is transparent to radiation of the first wavelength range and absorbent to radiation of the second wavelength range. If a material or an element is described here and in the following as “absorbent” for a certain radiation, it has in particular a absorption of at least 80% or at least 90% or at least 95% with respect to this radiation.

The intermediate layer comprises, for example, a glass. The intermediate layer is adapted, for example, so that it has a high transmission at a wavelength of 275 nm and is absorbent at a shorter wavelength. In particular, the material of the intermediate layer is adapted such that it is insensitive to radiation of the first wavelength range. This means that the intermediate layer is not decomposed or damaged by radiation of the first wavelength range. If, for example, the semiconductor chip is a sapphire chip that emits radiation in the UVC range during operation, i.e. the first wavelength range is the UVC range, the intermediate layer is preferably UV-stable.

In particular, the intermediate layer is free of organic material. Preferably, the intermediate layer consists entirely of inorganic materials. The material of the intermediate layer is adapted, for example, so that the intermediate layer can be heated by radiation of the second wavelength range.

According to at least one embodiment of the optoelectronic component, the first wavelength range has different wavelengths than the second wavelength range. For example, the first wavelength range and second wavelength range are each contiguous regions that do not overlap. In particular, this means that any wavelength that is in the first wavelength range is not included in the second wavelength range and vice versa.

In at least one embodiment, the optoelectronic semiconductor component comprises at least one optoelectronic semiconductor chip, at least one optical element and an intermediate layer between the at least one optoelectronic semiconductor chip and the at least one optical element. The at least one optoelectronic semiconductor chip is configured to emit radiation in a first wavelength range. The at least one optical element is formed with a material that is transparent to radiation in a second wavelength range. The intermediate layer comprises a material that is transparent to radiation of the first wavelength range and absorbent to radiation of the second wavelength range. The first wavelength range comprises different wavelengths than the second wavelength range.

The present optoelectronic component is based on the following technical considerations. Currently, for components comprising a semiconductor chip, in particular a semiconductor chip that emits in the UVC range, and a lens, a fluoropolymer lens is usually applied directly to the semiconductor chip by encapsulation or modeling. It is difficult to select process conditions in such a way that neither the semiconductor chip nor other materials are damaged, but sufficient component stability is still guaranteed. The main known problems here are delamination and reduced material service life. The reasons for this include high temperatures during curing of the fluoropolymer lens, which can also damage the semiconductor chip.

Alternative concepts implement glass lenses, which are applied to an optical substrate and fixed towards the semiconductor chip, for example. However, this results in a disadvantageous material transition from the material of the semiconductor chip to air for light extraction in the direction of radiation, followed by a material transition from air to glass and a further material transition from glass to air. Due to the total reflection that occurs, the lens effect is counteracted in addition to losses in terms of efficiency.

An additional possibility is the application of a glass lens via a so-called fusion bond. Here, however, very high demands are placed on the roughness and cleanliness of the surfaces of the semiconductor chip and the glass lens. Usually, a roughness of Ra less than 1 nm is required, where Ra is the mean roughness value. This can only be achieved with a special manufacturing process. For these processes, for example, an artificial wafer must be created for the glass lens and the semiconductor chip, whereby the lenses are embedded in a matrix material in order to subsequently achieve the required surface quality. After the fusion bond process, semiconductor chips with the lenses must be released from the matrix material. This involves a great deal of effort, which leads to very high process and development costs.

In the present optoelectronic component, use is made of the idea of attaching an optical element to an optoelectronic semiconductor chip by means of an intermediate layer. By using the intermediate layer, an air gap between the optical element and the optoelectronic semiconductor chip can be avoided. This increases the optical decoupling. By attaching the lens to a front side of the semiconductor chip, beam shaping in the forward direction can be achieved. Advantageously, this significantly improves the light extraction of the optoelectronic component. At the same time, total reflection, for example due to a material transition to air, can be reduced when coupling out radiation of the optoelectronic component. The operational life of the optoelectronic component can also be advantageously increased.

According to at least one embodiment of the optoelectronic component, the at least one optical element is set up for beam shaping of radiation of the first wavelength range and/or the second wavelength range. The at least one optical element is, for example, a lens, in particular a converging lens. Radiation of the first wavelength range, which is emitted by the optoelectronic semiconductor chip during intended operation, is directed in the main emission direction by means of the optical element, for example.

Alternatively or additionally, the optical element acts as a lens for radiation of the second wavelength range, which is directed onto the intermediate layer, for example during the manufacture of the optoelectronic component. The optical element focuses this radiation onto the intermediate layer, for example.

Alternatively, the at least one optical element can be a prism. The prism can be used, for example, to influence a main emission direction of the optoelectronic component. This can be particularly advantageous in a case in which the at least one optoelectronic semiconductor chip is a laser diode.

According to at least one embodiment of the optoelectronic component, the at least one optical element and the at least one optoelectronic semiconductor chip are positively connected to each other by means of the intermediate layer. In particular, this means that no further material is arranged between the at least one optoelectronic semiconductor chip and the intermediate layer or between the intermediate layer and at least one optical element. The intermediate layer is preferably directly adjacent to the at least one optoelectronic semiconductor chip and the at least one optical element. Advantageously, a material transition to a low-refractive material between the at least one optoelectronic semiconductor chip and the at least one optical element can thus be avoided, whereby light extraction from the optoelectronic component is increased.

According to at least one embodiment of the optoelectronic component, the first wavelength range is in the UV range of the electromagnetic spectrum and comprises wavelengths greater than or equal to 250 nm. For example, the first wavelength range comprises wavelengths up to and including 380 nm or up to and including 300 nm or up to and including 280 nm. For example, the optoelectronic component emits radiation with a peak wavelength of 275 nm during intended operation. The peak wavelength is the wavelength at which an emission spectrum of the optoelectronic component has its greatest intensity. The at least one optoelectronic semiconductor chip is therefore in particular a UV chip, for example a UV sapphire chip.

According to at least one embodiment of the optoelectronic component, the first wavelength range is in the UV range of the electromagnetic spectrum and comprises wavelengths greater than or equal to 200 nm. For example, the first wavelength range comprises wavelengths up to and including 380 nm or up to and including 300 nm or up to and including 280 nm. For example, the optoelectronic component emits radiation with a peak wavelength of 230 nm during intended operation. The at least one optoelectronic semiconductor chip is therefore in particular a UV chip, for example a UV sapphire chip.

According to at least one embodiment of the optoelectronic component, the second wavelength range comprises wavelengths between 180 nm and 230 nm inclusive or between 150 nm and 200 nm inclusive. The second wavelength range lies in particular in the UVC range of the electromagnetic spectrum. The second wavelength range preferably comprises shorter wavelengths than the first wavelength range.

Alternatively, it is possible that the second wavelength range comprises wavelengths that are greater than wavelengths from the first wavelength range. For example, the second wavelength range comprises wavelengths from the IR range of the electromagnetic spectrum.

According to at least one embodiment of the optoelectronic component, the at least one optical element has a higher melting point than the intermediate layer. For example, the melting point of the at least one optical element is twice or 1.5 times or 1.3 times as high as the melting point of the intermediate layer. As a result, the intermediate layer between the at least one optoelectronic semiconductor chip and the at least one optical element can be at least partially melted by heating without the at least one optical element being impaired. A melting point of the intermediate layer is, for example, between 700° C. and 800° C. inclusive. A melting point of the optical element is, for example, more than 1500° C.

According to at least one embodiment of the optoelectronic component, the intermediate layer comprises a matrix material in which filling particles are provided. The filling particles are formed in particular with a material that is transparent or reflective for radiation of the first wavelength range and absorbent for radiation of the second wavelength range. The matrix material is preferably transparent to radiation of the first and second wavelength range. The matrix material is, for example, a fluoropolymer. The filler particles are, for example, silica particles, also known as fused silica.

According to at least one embodiment of the optoelectronic component, the at least one optical element is a sapphire lens. In the case where the at least one optoelectronic semiconductor chip is a sapphire chip, a sapphire lens as the at least one optical element is particularly advantageous, since the at least one optical element is adapted to the chip substrate of the semiconductor chip, for example with respect to thermal expansion coefficients and/or refractive index.

According to at least one embodiment of the optoelectronic component, thermal expansion coefficients of the at least one optical element, the at least one optoelectronic semiconductor chip and the intermediate layer differ from each other by at most 0.5 ppm/K. For example, if the at least one optoelectronic semiconductor chip is a sapphire chip and the at least one optical element is a sapphire lens, they have the same thermal expansion coefficient. In this case, the thermal expansion coefficient of the at least one optoelectronic semiconductor chip and of the at least one optical element is, for example, 7.9 ppm/K. Advantageously, the intermediate layer is then adapted in such a way that a thermal expansion coefficient of the intermediate layer differs by at most 0.5 ppm/K from the coefficient of thermal expansion of the at least one optoelectronic semiconductor chip and of the at least one optical element. For example, in this case the thermal expansion coefficient of the intermediate layer is 7.7 ppm/K.

The adapted thermal expansion coefficients of the at least one optoelectronic semiconductor chip, the at least one optical element and the intermediate layer can reduce thermal stress in the optoelectronic component.

According to at least one embodiment, the optoelectronic component comprises a plurality of optoelectronic semiconductor chips in a chip array. Furthermore, the optoelectronic component comprises a plurality of optical elements in a lens array. The chip array and the lens array are positively connected to each other by means of the intermediate layer.

According to at least one embodiment, the at least one optoelectronic semiconductor chip is arranged on a carrier substrate. A connection layer is arranged between the carrier substrate and the at least one optoelectronic semiconductor chip. The carrier substrate is formed, for example, with a ceramic. The connection layer is preferably a solder layer that electrically conductively connects the at least one optoelectronic semiconductor chip to the carrier substrate. The connection layer comprises, for example, gold and/or tin. In particular, the connection layer can be formed with AuSn. On a side facing the at least one optoelectronic semiconductor chip, the carrier substrate preferably comprises connection points via which the at least one optoelectronic semiconductor chip can be contacted and supplied with current. On a side opposite the connection points, the carrier substrate comprises, for example, a metallization. In particular, the connection points are electrically conductively connected to the metallization via through-contacts through the carrier substrate. It is possible that the connection points, the through-contacts and the metallization are formed in one piece and each comprise at least one metal such as copper.

According to at least one embodiment, the optoelectronic component comprises a frame on the carrier substrate. The frame surrounds the at least one optoelectronic semiconductor chip in lateral directions. The frame is formed, for example, with a polymer and/or epoxy or alternatively comprises silicon. Lateral directions are, for example, directions that are perpendicular to the main emission direction.

The frame is preferably provided with a reflective coating on surfaces facing the optoelectronic semiconductor chip. The surfaces facing at least one optoelectronic semiconductor chip are preferably inclined. This means that these surfaces have an acute angle relative to the main plane of the active zone. The reflective coating is set up to be reflective for radiation in the first wavelength range and preferably comprises at least one metal, for example aluminum. Advantageously, the frame and the reflective coating can be used to direct radiation, which is emitted laterally from the semiconductor chip during intended operation, in the main emission direction.

A method of manufacturing an optoelectronic component is further disclosed. In particular, the method can be used to manufacture an optoelectronic component as described herein. This means that all features disclosed for the method are also disclosed for the component and vice versa.

In at least one embodiment of the method, at least one optical element is provided in a step A). In a step B), an intermediate layer is applied to a main surface of the at least one optical element. The intermediate layer is applied, for example, by dispensing. Alternatively, a material for the intermediate layer can, for example, be applied as a platelet, powder or paste and then melted. It is also possible for the material for the intermediate layer to be applied by sputtering, vapor deposition, coating or spraying. At least one optoelectronic semiconductor chip is attached to a side of the intermediate layer facing away from the at least one optical element.

In a step C) of the method, the at least one optoelectronic semiconductor chip is attached to a side of the intermediate layer facing away from the at least one optical element. In particular, the at least one optical element with the intermediate layer is placed on the at least one optoelectronic semiconductor chip. An adhesion promoter such as glycerine can be used to prevent the at least one semiconductor chip from slipping relative to the at least one optical element. In further process steps, the adhesion promoter is preferably removed again. For example, the adhesion promoter is vaporized.

In a further step D), the at least one optoelectronic semiconductor chip is connected to the at least one optical element by irradiating the intermediate layer with radiation of a second wavelength range.

The at least one optical element is preferably formed with a material that is transparent to radiation of the second wavelength range. Radiation of the second wavelength range is absorbed in the intermediate layer, so that the intermediate layer is heated, at least in places, to a temperature above a melting temperature of the intermediate layer. The intermediate layer advantageously acts like a solder, for example a glass solder.

In particular, the intermediate layer comprises a material that is absorbent for radiation of the second wavelength range and transparent for radiation of a first wavelength range. Radiation of the first wavelength range is emitted, for example, by the at least one optoelectronic semiconductor chip during intended operation.

Advantageously, heat is only applied locally to the intermediate layer during the process, which means that the thermal load during the process remains relatively low. In particular, the at least one optoelectronic semiconductor chip is only slightly heated. Due to the low thermal load, the overall operational life of the optoelectronic component can be increased and a risk of premature damage to the at least one semiconductor chip during the manufacture of the component can be reduced. The operational life of the optoelectronic component can thus be increased.

According to at least one embodiment of the method, in step D) the intermediate layer is irradiated with radiation of the second wavelength range through the optical element. The at least one optical element is, for example, configured for beam shaping of radiation of the second wavelength range. By irradiating the intermediate layer through the at least one optical element, radiation of the second wavelength range can be focused specifically onto the intermediate layer. This can reduce thermal load on the at least one optoelectronic semiconductor chip and the at least one optical element.

According to at least one embodiment of the method, laser radiation with a wavelength between 100 nm and 250 nm inclusive is used in step D), preferably between 120 nm and 230 nm inclusive. A light source for such laser radiation is, for example, an F₂-laser, an Xe₂-laser, a KrCl-laser, a KrF-laser or preferably an ArF-laser. It is possible for the light source to be operated in pulsed mode.

According to at least one embodiment of the method, the at least one optical element has a lateral extent with respect to the main surface that is greater than a beam width of the laser radiation. The beam width of the laser radiation is measured, for example, perpendicular to a direction of propagation of the laser radiation. The lateral expansion is, for example, the maximum expansion of the at least one optical element in the lateral direction. The lateral extent of the at least one optical element is, for example, between 1000 μm and 6000 μm inclusive, for example about 2500 μm or about 5000 μm. Preferably, in this or in all embodiments, the at least one optical element has a lateral extent that is at least as large as a lateral extent of the main emission area of the at least one optoelectronic semiconductor chip. In this case, the main emission area is completely covered by the at least one optical element, particularly when in view of the main emission area. A beam width of the laser radiation is, for example, approximately 1740 μm. In particular, the at least one optical element is configured for beam shaping of the laser radiation. The laser radiation can be focused onto the intermediate layer by the at least one optical element. This can reduce the thermal load on the at least one optoelectronic semiconductor chip and the at least one optical element.

According to at least one embodiment of the method, the intermediate layer is homogeneously irradiated with the laser radiation in step D). In particular, this means that the laser radiation in the region of the intermediate layer has a width that is equal to or greater than a lateral extent of the intermediate layer. The lateral expansion of the intermediate layer is measured perpendicular to the direction of propagation of the laser radiation. Advantageously, the intermediate layer can thus be heated with a single irradiation process and the at least one optical element can be efficiently connected to the at least one optoelectronic semiconductor chip.

Alternatively, it is possible for the laser radiation in the region of the intermediate layer to have a beam width that is smaller than the lateral extent of the intermediate layer. In this case, the intermediate layer can be irradiated with the laser radiation in a grid pattern.

According to at least one embodiment of the method, in step B) the at least one optical element is heated above a melting temperature of the intermediate layer so that a material of the intermediate layer is evenly distributed over the main surface. For example, the at least one optical element is heated to at least 700° C. or at least 800° C. and at most 900° C. or at most 1000° C. For example, the at least one optical element is heated by means of a heating plate. For example, the at least one optical element is provided on the heating plate. Preferably, the at least one optical element has a higher melting temperature than the intermediate layer. This prevents partial melting of the optical element.

According to at least one embodiment of the method, before step C), the at least one optoelectronic semiconductor chip is applied to a carrier substrate. During step D), a connection layer between the carrier substrate and the at least one optoelectronic semiconductor chip is heated to at most 250° C. The connection layer is, for example, a solder layer. The connection layer comprises, for example, gold and/or tin or is formed with AuSn.

According to at least one embodiment of the method, a plurality of optical elements is provided in a lens array. The intermediate layer is deposited on the lens array. The lens array is connected to a chip array comprising a plurality of optoelectronic semiconductor chips, such that at least one optical element is associated with each optoelectronic semiconductor chip. It is possible for each optoelectronic semiconductor chip to be assigned exactly one optical element.

According to at least one embodiment of the method, a composite of the lens array and the chip array is separated into a plurality of optical devices.

### BRIEF DESCRIPTION OF THE DRAWINGS

Further advantages and advantageous embodiments and further embodiments of the optoelectronic component and the method result from the following exemplary embodiment shown in connection with the schematic drawings. Identical, similar and identically acting elements are provided with the same reference signs in the figures. The figures and the proportions of the elements shown in the figures are not to be regarded as being to scale. Rather, individual elements may be shown in exaggerated size for better visualization and/or better comprehensibility.

FIGS. 1, 2 and 4 show sectional views of exemplary embodiments of the optoelectronic component;

FIG. 3 shows a detailed view of the intermediate layer according to an exemplary embodiment in sectional view;

FIGS. 5 to 11 show sectional views of various stages of a method for manufacturing an optoelectronic component according to two exemplary embodiments;

FIGS. 12, 13, 15 and 17 show graphical representations of material properties of a material for an intermediate layer according to an exemplary embodiment;

FIG. 14 shows results of a simulation of the decoupling efficiency of an optoelectronic component; and

FIG. 16 shows a graphical representation of material properties of a material for an optical element.

### DETAILED DESCRIPTION OF ILLUSTRATIVE EMBODIMENTS

The optoelectronic component 1 of FIG. 1 comprises an optoelectronic semiconductor chip 2 and an optical element 3. An intermediate layer 4 is arranged between the semiconductor chip 2 and the optical element 3.

The optoelectronic semiconductor chip 2 comprises a semiconductor layer sequence 22. The semiconductor layer sequence 22 is based on a III-V compound semiconductor material. The semiconductor layer sequence 22 comprises an active zone, not shown. Electromagnetic radiation is generated in the active zone during the intended operation. During intended operation, this electromagnetic radiation is emitted by the optoelectronic semiconductor chip 2 and thus by the optoelectronic component 1. The radiation is radiation of a first wavelength range 5.

The radiation of the first wavelength range 5 is electromagnetic radiation of the UV range, in particular the UVC range of the electromagnetic spectrum. For example, the optoelectronic component 1 emits radiation with a peak wavelength of 275 nm during intended operation. The peak wavelength is the wavelength at which an emission spectrum of the optoelectronic component 1 has its greatest intensity.

The optoelectronic semiconductor chip 2 further comprises a chip substrate 21. The semiconductor layer sequence 22 is deposited on the chip substrate 21. The chip substrate 21 is a sapphire substrate. The semiconductor chip 2 is therefore a sapphire chip, in particular a volume emitter.

Contact points 23 for making electrical contact with the semiconductor layer sequence 22 are arranged on a side of the semiconductor layer sequence 22 facing away from the chip substrate 21. The semiconductor layer sequence 22 can be supplied with current via the contact points 23 during intended operation. The optoelectronic semiconductor chip 2 is thus a flip chip.

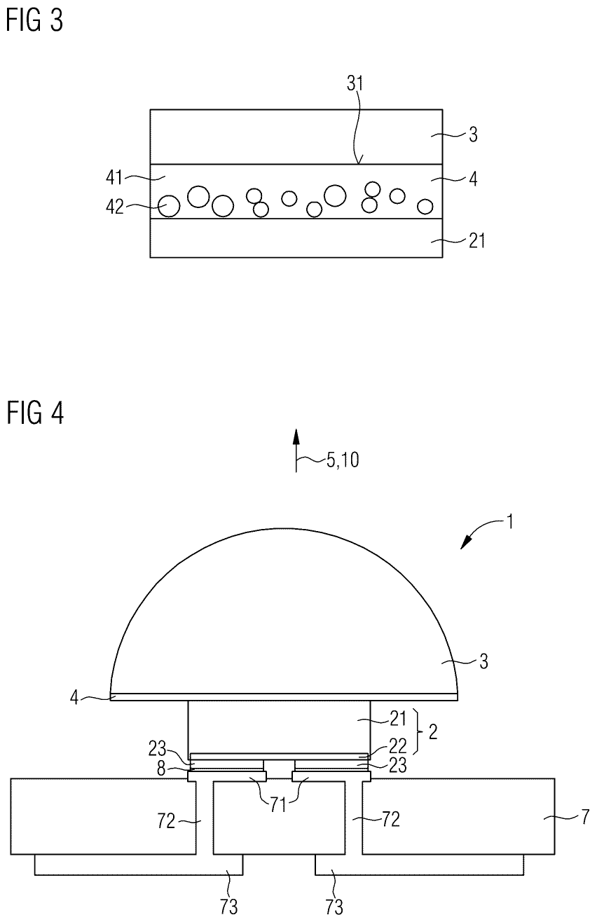

The intermediate layer 4 is arranged on a side of the chip substrate 21 facing away from the semiconductor layer sequence 22. The intermediate layer 4 comprises a matrix material 41 in which filling particles 42 are embedded. In the present exemplary embodiment, the matrix material 41 is formed with a fluoropolymer. The filling particles 42 are silica particles (cf. FIG. 3).

The intermediate layer 4 is permeable to radiation of the first wavelength range 5. Intermediate layer 4 is absorbent for radiation of a second wavelength range 6, which comprises different wavelengths than the first wavelength range 5. The second wavelength range 6 comprises, for example, shorter wavelengths than the first wavelength range 5. For example, the second wavelength range 6 comprises UV radiation of a wavelength of less than 230 nm. Alternatively, however, it is also possible for the second wavelength range to have longer wavelengths than the first wavelength range 5. For example, the second wavelength range 6 may comprise radiation in the IR range.

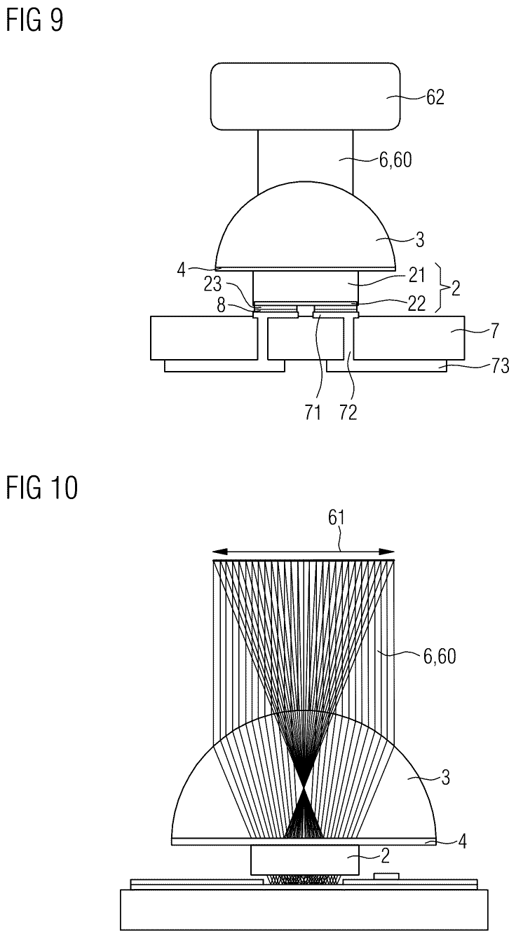

By irradiating the intermediate layer 4 with radiation of the second wavelength range 6, the optical element 3 can be attached to the semiconductor chip 2. The intermediate layer 4 is heated by absorbing the radiation of the second wavelength range 6, so that a positively connection is created between the semiconductor chip 2 and the optical element 3 (cf. FIG. 9).

The intermediate layer 4 has a thickness of between 1 μm and 5 μm. The thickness of the intermediate layer 4 is selected in such a way that a roughness of a side of the semiconductor chip 2 and/or the optical element 3 facing the intermediate layer 4 is compensated.

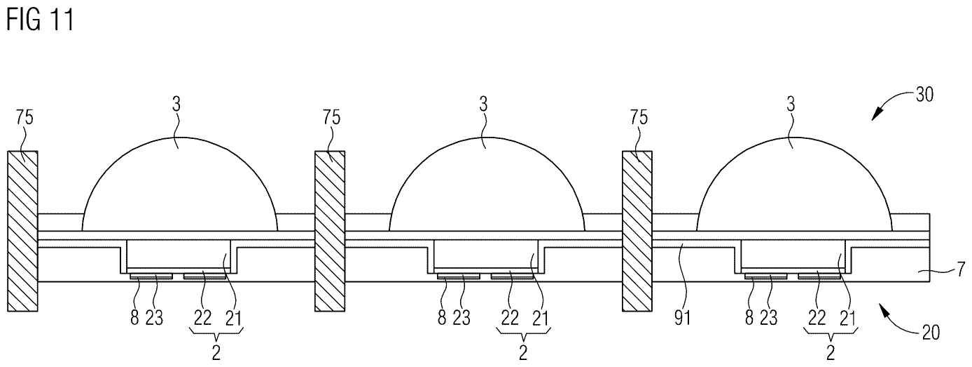

The optical element 3 is configured for beam shaping the radiation of the first wavelength range 5. The optical element 3 can be used to direct radiation in the direction of a main emission direction 10. The main emission direction 10 is preferably perpendicular to a main extension direction of the semiconductor layer sequence 22. In addition, it is possible that the optical element 3 is configured for beam shaping of radiation of the second wavelength range 6 (cf. FIG. 11).

In the present exemplary embodiment, the optical element 3 is a lens. In the present exemplary embodiment, the optical element 3 is formed with sapphire. By using sapphire for the optical element 3 and the chip substrate 21, thermal stresses in the optical component 1 can be reduced. The optical element 3 is transparent to radiation of the first and second wavelength range 5, 6. The optical element 3 preferably has a maximum lateral expansion of 5000 μm. The lateral expansion is measured in a direction parallel to a main extension plane of the semiconductor layer sequence 22.

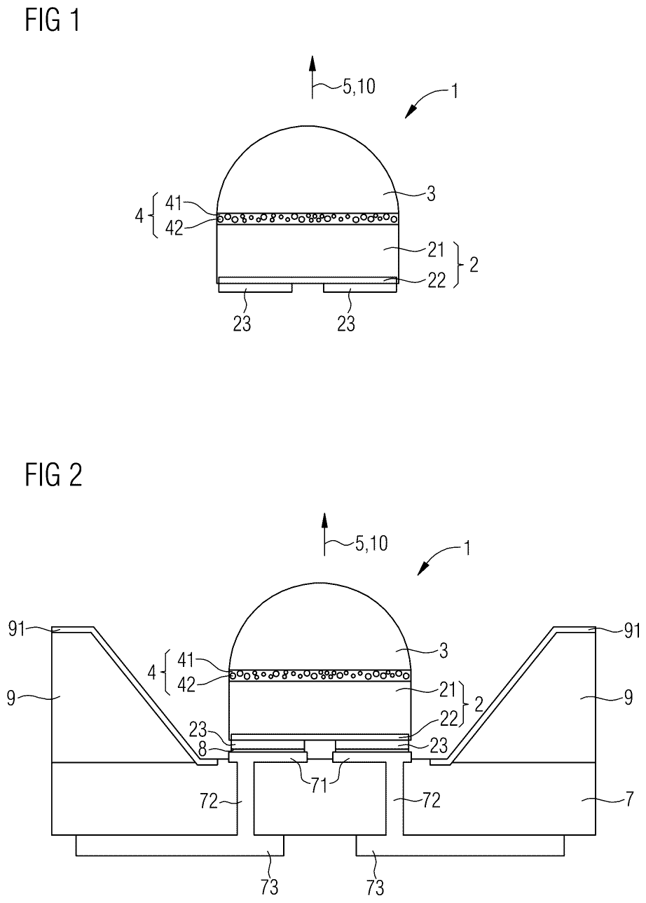

FIG. 2 shows an optoelectronic component 1 according to a second exemplary embodiment. The optoelectronic component 1 of FIG. 2 differs from the optoelectronic component 1 of FIG. 1 in that the optoelectronic component 1 of FIG. 1 is applied to a carrier substrate 7. The carrier substrate 7 comprises connection points 71 on a side facing the semiconductor chip 2 and a metallization 73 on a side opposite the connection points 71. The metallization 73 is electrically conductively connected to the connection points 71 via through-contacts 72 with the carrier substrate 7. The carrier substrate 7 is formed with a ceramic. The connection points 71, the through-contacts 72 and the metallization 73 each comprise at least one metal, for example copper. The optoelectronic component 1 can be externally contacted and supplied with current via the metallization 73. The connection points, the through-contacts and the metallization 73 can be manufactured in one piece.

The contact points 23, via which the semiconductor layer sequence 22 can be supplied with current during intended operation, are electrically conductively connected to the connection points 71 by means of a connection layer 8. The connection layer 8 is a solder layer, which in particular comprises AuSn.

The optoelectronic component 1 of FIG. 2 further comprises a frame 9. The frame is applied to a main side of the carrier substrate 7 and surrounds the semiconductor chip 2 and the optical element 3 in lateral directions. Lateral directions are directions perpendicular to the main emission direction 10. The frame 9 is formed, for example, with a polymer. For example, the frame is an epoxy mold. Alternatively, the frame 9 is a silicon frame bonded to the carrier substrate 7.

The frame is provided with a coating 91 on the surfaces facing the semiconductor chip 2. These surfaces are inclined and have an acute angle with respect to a main direction of extension of the semiconductor layer sequence 22. The coating 91 is reflective for radiation of the first wavelength range 5. The coating 91 preferably comprises a metal such as aluminum. The frame 9 with the reflective coating 91 allows the radiation of the first wavelength range 5, which is emitted by the optoelectronic component 1 during intended operation, to be directed in the main emission direction 10.

In an alternative exemplary embodiment, the optoelectronic component 1 does not comprise a frame 9. In this case, the optoelectronic semiconductor chip 2 is mounted on the carrier substrate 7 without a frame 9 surrounding it. In this exemplary embodiment, beam shaping and/or directing of the radiation in the main emission direction 10 takes place predominantly or completely through the optical element 3. In all other aspects, this exemplary embodiment corresponds to the exemplary embodiment of FIG. 2.

The optoelectronic component 1 of FIG. 4 differs from the optoelectronic component of FIG. 1 in that the intermediate layer is formed with a glass. The glass is transparent for radiation of the first wavelength range 5 and absorbent for radiation of the second wavelength range 6. Thus, with regard to the connection of the optoelectronic semiconductor chip 2 and the optical element 3, the intermediate layer 4 according to FIG. 4 has the same function and properties as the intermediate layer 4 according to FIGS. 1 and 2.

The intermediate layer 4 is formed with a glass such that a thermal expansion coefficient of the intermediate layer 4 differs from the thermal expansion coefficients of the chip substrate 21 and the optical element 3 by less than 0.5 ppm/K. For example, the thermal expansion coefficient of the chip substrate 21 and the optical element 3 is 7.9 ppm/K in the case where one material of the chip substrate 21 and the optical element 3 is sapphire. For the intermediate layer 4, for example, a glass that has a thermal expansion coefficient of 7.7 ppm/K is used. Due to the adapted thermal expansion coefficient of the intermediate layer 4, thermal stresses in the optoelectronic component 1 can be reduced.

In addition, the optoelectronic component 1 of FIG. 4 differs from the optoelectronic component 1 of FIG. 1 in that the optoelectronic component of FIG. 4 is applied to a carrier substrate 7. In particular, the carrier substrate 7 has the same features as the carrier substrate 7 of FIG. 2.

In a first process step in the process for manufacturing an optoelectronic component 1 according to FIGS. 5 to 11, an optical element 3 is provided (FIG. 5). The optical element 3 has, for example, the same features as the optical element 3 of FIG. 1. The optical element 3 is provided on a heating plate 101.

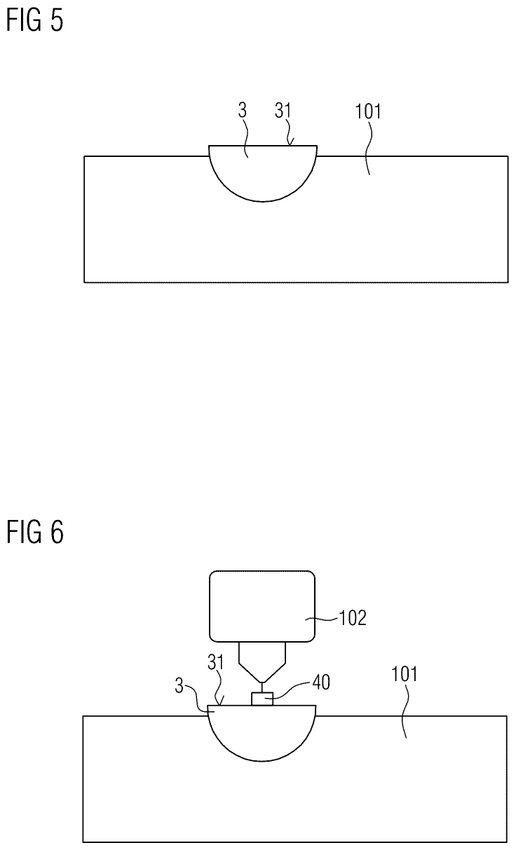

In a subsequent process step, material of the intermediate layer 40 is applied to a main surface 31 of the optical element 3 (FIG. 6). The material of the intermediate layer 40 is applied by dispensing. A dispenser 102 is used for application. Alternatively, the material of the intermediate layer 40 can also be applied as a glass platelet or as a paste or as a powder. It is also possible for the material of the intermediate layer 40 to be applied by sputtering, vapor deposition, coating or spraying.

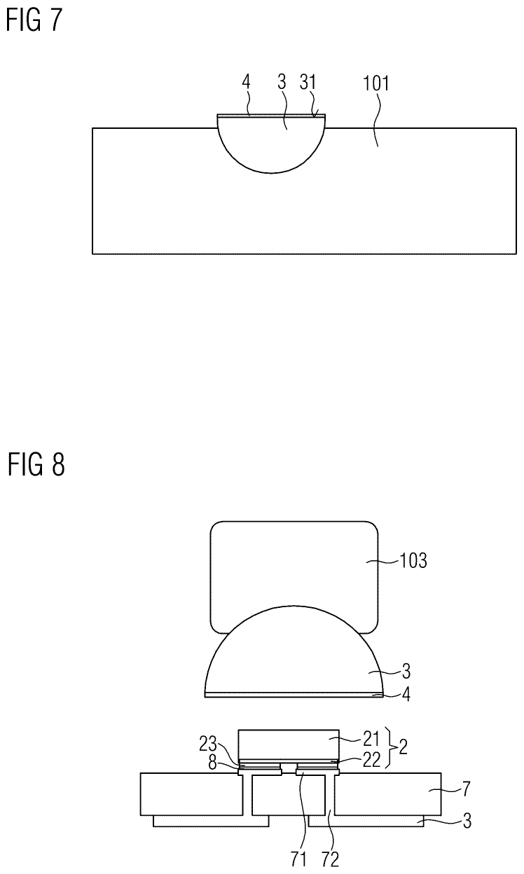

In a further process step, the material of the intermediate layer 40 is evenly distributed on the main surface 31 of the optical element 3 and the intermediate layer 4 is formed (FIG. 7). In this process step, the optical element 3 is heated by means of the heating plate 101. The optical element 3 is heated to a temperature that is above a melting temperature of the intermediate layer 4. For example, the optical element 3 is heated to 800° C. The intermediate layer 4 preferably has the same features as the intermediate layer 4 of FIG. 4.

In a subsequent step, the optical element 3 with the intermediate layer 4 is connected to a semiconductor chip 2. The semiconductor chip 2 has, for example, the same features as the semiconductor chip 2 according to FIG. 1. The semiconductor chip 2 is provided, for example, on a carrier substrate 7. The carrier substrate 7 preferably has the same features as the carrier substrate 7 of FIG. 4.

To connect the optical element 3 to the semiconductor chip 2, the optical element 3 is placed face to face to the semiconductor chip 2. The optical element 3 is placed over the semiconductor chip 2 by means of a transfer device 103 (FIG. 8). An adhesion promoter (not shown), such as glycerin, can be used to place the optical element 3. The adhesion promoter can be removed again in a process step, not shown. For example, the adhesion promoter is vaporized.

Subsequently, the intermediate layer 4 is irradiated with radiation of the second wavelength range 6 (FIG. 9). The radiation of the second wavelength range 6 is laser radiation 60. The laser radiation 60 is emitted by a light source 62. The intermediate layer 4 is irradiated through the optical element 3. The light source 62 is, for example, an ArF laser that emits laser radiation 60 with a wavelength of 193.3 nm.

For example, the laser beam 60 has a beam width 61 of 1740 μm. The optical element 3 has a lateral expansion of 2500 μm, for example. Both the beam width 62 and the lateral expansion of the optical element 3 are measured perpendicular to the direction of propagation of the laser beam 60. The optical element 3 is set up for beam shaping of the laser radiation 60 (FIG. 10).

The laser radiation 60 is absorbed in the intermediate layer 4. As a result, the intermediate layer 4 is heated above its melting temperature and melts. After the intermediate layer 4 cools down after the irradiation with the laser radiation 60 is terminated, the optoelectronic semiconductor chip 2 and the optical element 3 are positively connected to each other.

The optical element 3 focuses the laser radiation 60 in the intermediate layer 4 (FIG. 10). The laser radiation 60 irradiates an area of the intermediate layer 4 that covers the semiconductor chip 2 in the top view of the optoelectronic semiconductor chip 2. This means that the intermediate layer 4 is homogeneously irradiated with the laser radiation 60 in a region in which it borders on the semiconductor chip 2. Thus, the intermediate layer 4 can be irradiated in a single irradiation step and a form-fit connection between the semiconductor chip 2 and the optical element 3 can be achieved.

This makes it possible to avoid an air gap between the semiconductor chip 2 and the optical element 3. Furthermore, there is no large jump in the refractive index between the substrate 21 and the optical element 3, which increases the decoupling efficiency of the optoelectronic component 1.

In the method step shown in FIG. 11, the method was carried out in a manner deviating from the method of FIGS. 5 to 10 in such a way that a lens array 30 is provided, to which the intermediate layer 4 is applied. The lens array 30 comprises a plurality of optical elements 3. Subsequently, a chip array 20 is applied to the intermediate layer 4 on a side facing away from the lens array 30. The chip array 20 comprises a plurality of optoelectronic semiconductor chips 2.

Subsequently, a reflective coating 91 is applied to a side of the intermediate layer 4 facing away from the lens array 30 and to side surfaces of the optoelectronic semiconductor chips 2. The reflective coating 91 comprises at least one metal such as aluminum.

The optoelectronic semiconductor chips 2 are subsequently encapsulated using a molding process to create a carrier substrate 7.

In a further process step, the lens array 30 and the chip array 20 are separated along separation lines 75. The separation lines 75 run between the optical elements 3 of the lens array 30. After separation, each optoelectronic semiconductor chip 2 is assigned to exactly one optical element 3.

Alternatively, the separation step can be omitted, resulting in an optoelectronic component 1 comprising a plurality of optical elements 3 and optoelectronic semiconductor chips 2.

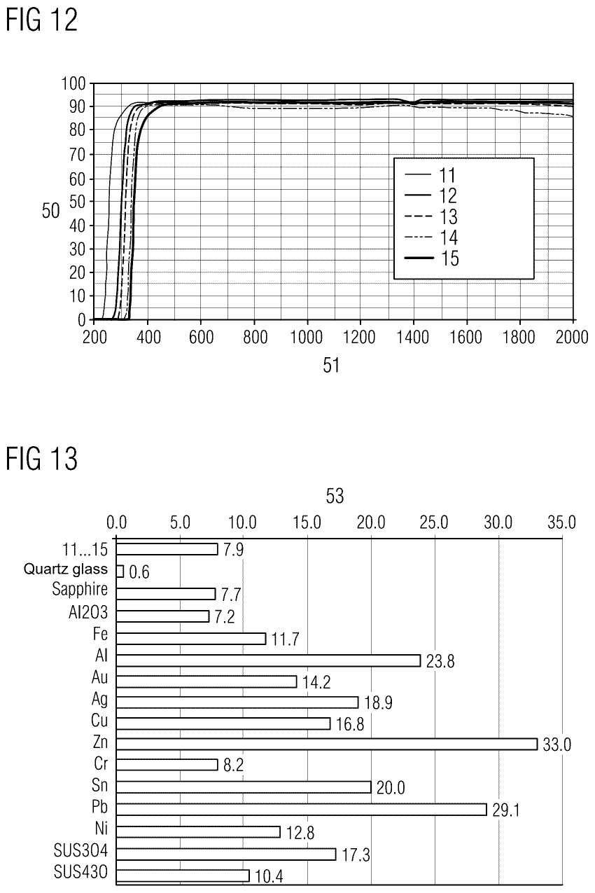

FIG. 12 and FIG. 13 show material properties of glasses that can be used for the intermediate layer 4. For example, such glasses are used for the intermediate layer 4 of the optoelectronic component 1 according to FIG. 4.

The glasses 11 to 15 each have a vanishing transmission 50 at a wavelength 51 below 200 nm. This means that the glasses 11 to 15 are not transparent but absorbent in this wavelength range (FIG. 12). In a wavelength range with a wavelength 51 greater than 400 nm, all glasses 11 to 15 show a transmission of over 85% up to over 90%. Glass 11 in particular already shows a transmission 50 of almost 90% at a wavelength 51 of approximately 250 nm. This makes glass 11 particularly suitable for the intermediate layer 4, as it is transparent at the peak wavelength of the optoelectronic semiconductor chip 2. At the same time, the glass 11 shows an absorption of almost 100% at a wavelength of 193.90 nm, such as the second wavelength range 6.

A thermal expansion coefficient 53 of the glasses 11 to 15 is adapted to the coefficient of thermal expansion 53 of sapphire (FIG. 13). A difference in the thermal expansion coefficients 53 of the glasses 11 to 15 to the thermal expansion coefficients of sapphire is only 0.2 ppm/K. In comparison, a difference in the thermal expansion coefficients between quartz glass and sapphire is over 7 ppm/K. The glasses 11 to 15 are thus particularly suitable for the intermediate layer in order to reduce thermal stresses in the optoelectronic component 1.

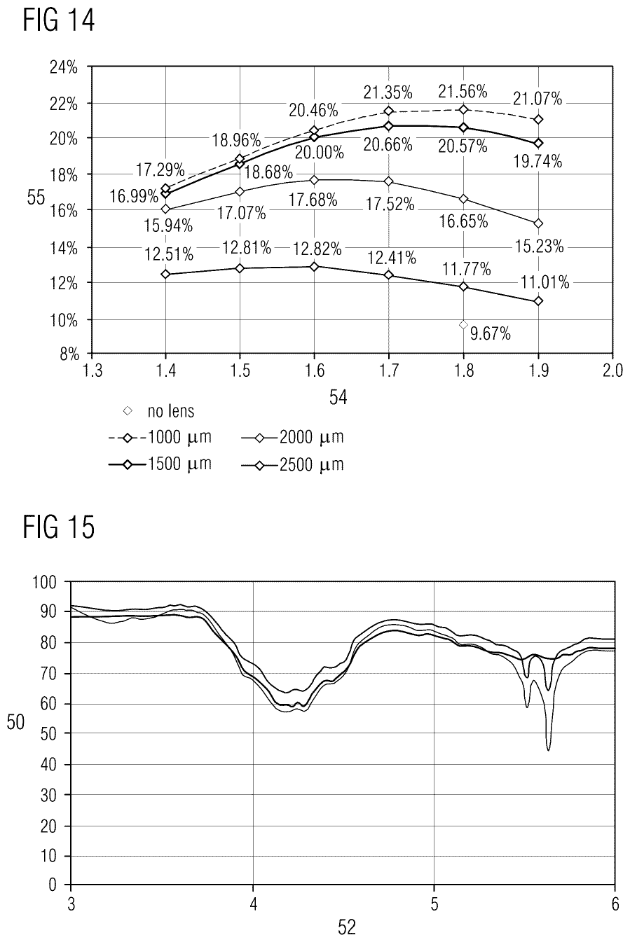

FIG. 14 shows results of a simulation in which decoupling efficiency 55 is shown as a function of the refractive index 54 of the optical element and its maximum lateral expansion. In principle, the best results are achieved with a lateral expansion of the optical element 3 of 2500 μm. The maximum decoupling efficiency is achieved with a lens whose material has a refractive index of 1.8. A suitable material for optical element 3 is therefore sapphire, which has a refractive index of 1.8.

FIG. 15 shows a transmission 50 for a fluoropolymer, such as is used as matrix material 41 for an intermediate layer 4. Different curves in FIG. 15 refer to different fluoropolymer variants, for example the so-called Cytop_CTL-A, CTX-A and CTX-S variants. It can be seen that for short-wave radiation with a wavelength 52 of less than 3.5 μm, the transmission 50 is almost 90% for all variants. This means that the fluoropolymer is suitable as a matrix material 41 as it is transparent to radiation of both the first wavelength range and the second wavelength range 6.

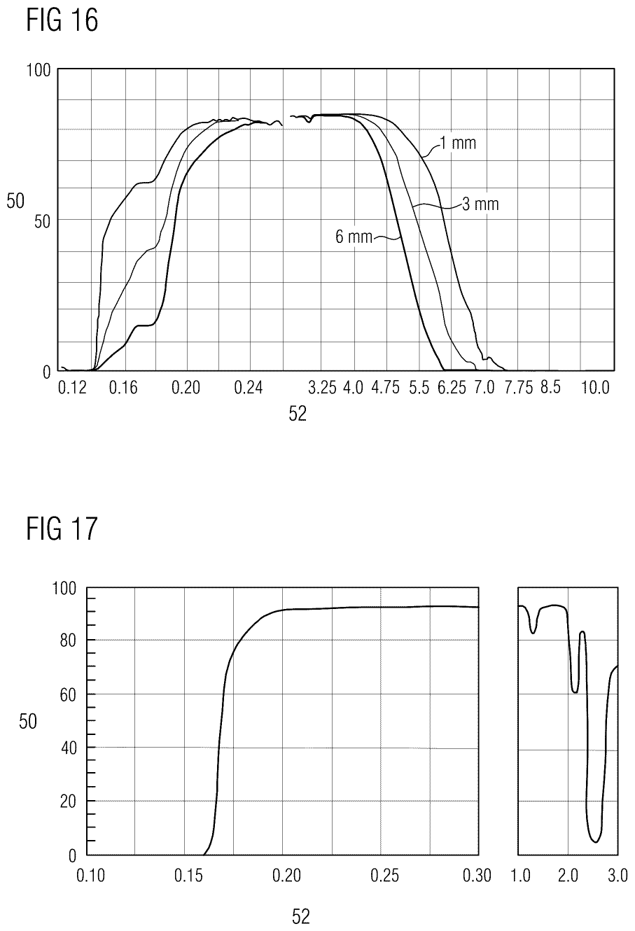

FIG. 16 shows the transmission 50 of sapphire in % as a function of the wavelength 52 in μm for different thicknesses. It can be seen that the transmission 50 for wavelengths 52 above 0.2 μm is more than 60% for all thicknesses and for wavelengths 52 above 0.25 μm more than 90% for all thicknesses. Sapphire is thus suitable as a material for the optical element 3, as it is largely transparent both for radiation of the first wavelength range and for radiation of the second wavelength range 6.

FIG. 17 shows the transmission 50 of silica particles in % as a function of the wavelength 52 in μm. This shows that transmission 50 decreases for wavelengths below 0.2 μm, which means that absorption increases. In addition, at a wavelength 52 of approximately 2.6 μm, the transmission 50 shows a local minimum, which means that the absorption at this wavelength 52 shows a local maximum. Thus, silica particles are suitable as filling particles 42 in a matrix material 41 for an intermediate layer 4, since heat can be selectively coupled into the intermediate layer by the absorption of the silica particles at certain wavelengths.

The invention is not limited to the description based on the exemplary embodiment. Rather, the invention includes any new feature as well as any combination of features, which includes in particular any combination of features in the patent claims, even if this feature or combination itself is not explicitly stated in the patent claims or embodiments.

1.-18. (canceled)

19. An optoelectronic component comprising:
at least one optoelectronic semiconductor chip configured to emit radiation in a first wavelength range;
at least one optical element; and
an intermediate layer between the at least one optoelectronic semiconductor chip and the at least one optical element,
wherein the intermediate layer is configured to attach the at least one optoelectronic semiconductor chip to the at least one optical element,
wherein the at least one optical element comprises a material that is transparent to radiation of a second wavelength range,
wherein the intermediate layer comprises a material that is transparent to the radiation of the first wavelength range and absorbent to the radiation of the second wavelength range,
wherein the intermediate layer is free from an organic material, and
wherein the first wavelength range comprises other wavelengths than the second wavelength range.

20. The optoelectronic component according to claim 19, wherein the at least one optical element is configured for beam shaping of the radiation of the first wavelength range and/or the second wavelength range.

21. The optoelectronic component according to claim 19, wherein the at least one optical element and the at least one optoelectronic semiconductor chip are positively connected to each other by the intermediate layer.

22. The optoelectronic component according to claim 19,
wherein the first wavelength range comprises wavelengths in an UV region of an electromagnetic spectrum with wavelengths greater than or equal to 250 nm, and
wherein the second wavelength range comprises wavelengths between 180 nm and 230 nm, inclusive.

23. The optoelectronic component according to claim 19,
wherein the first wavelength range comprises wavelengths in an UV range of an electromagnetic spectrum with wavelengths greater than or equal to 200 nm, and
wherein the second wavelength range comprises wavelengths between 150 nm and 200 nm, inclusive.

24. The optoelectronic component according to claim 19, wherein the at least one optical element has a higher melting point than the intermediate layer.

25. The optoelectronic component according to claim 19,
wherein the intermediate layer comprises a matrix material in which filling particles are provided,
wherein the filling particles comprise a material that is transparent to the radiation of the first wavelength range and absorbent to the radiation of the second wavelength range.

26. The optoelectronic component according to claim 19, wherein the at least one optical element is a sapphire lens.

27. The optoelectronic component according to claim 19, wherein thermal expansion coefficients of the at least one optical element, the at least one optoelectronic semiconductor chip and the intermediate layer differ from each other by at most 0.5 ppm/K.

28. The optoelectronic component according to claim 19, further comprising:
wherein the at least one optoelectronic semiconductor chip comprises a plurality of optoelectronic semiconductor chips provided in a chip array,
wherein the at least one optical element comprises a plurality of optical elements provided in a lens array, and
wherein the chip array and the lens array are positively connected to one another by the intermediate layer.

29. A method comprising:
providing at least one optical element;
applying an intermediate layer to a main surface of the at least one optical element;
attaching at least one optoelectronic semiconductor chip to a side of the intermediate layer facing away from the at least one optical element; and
connecting the at least one optical element to the at least one optoelectronic semiconductor chip by irradiating the intermediate layer with radiation of a second wavelength range,
wherein the at least one optical element comprises a material that is transparent for radiation of the second wavelength range, and
wherein the radiation of the second wavelength range is absorbed in the intermediate layer so that the intermediate layer is heated at least in places to a temperature above a melting temperature of the intermediate layer.

30. The method according to claim 29, wherein irradiating the intermediate layer comprises irradiating the intermediate layer with the radiation of the second wavelength range through the optical element.

31. The method according to claim 30,
wherein irradiating the intermediate layer comprises using laser radiation having a wavelength between 120 nm and 230 nm, inclusive,
wherein the at least one optical element has a lateral extent in view of the main surface that is greater than a beam width of the laser radiation, and
wherein the at least one optical element is configured for beam shaping of the laser radiation.

32. The method according to claim 31, wherein irradiating the intermediate layer comprises homogenously irradiating the intermediate layer with the laser radiation.

33. The method according to claim 29, wherein applying the intermediate layer comprises heating the at least one optical element above the melting temperature of the intermediate layer so that a material of the intermediate layer is distributed over the main surface.

34. The method according to claim 29, further comprising:
before attaching the at least one optoelectronic semiconductor chip, the at least one optoelectronic semiconductor chip is deposited on a carrier substrate; and
while connecting the at least one optical element, heating a connection layer between the carrier substrate and the at least one optoelectronic semiconductor chip to at most 250° C.

35. The method according to claim 29, further comprising:
providing a plurality of optical elements in a lens array;
applying the intermediate layer to the lens array; and
connecting the lens array to a chip array comprising a plurality of optoelectronic semiconductor chips so that the at least one optical element is associated with each optoelectronic semiconductor chip.

36. The method according to claim 35, further comprising singulating a composite of the lens array and the chip array into a plurality of optical devices.
